(19) United States
(12) Patent Application Publication
(10) Pub. No.: US 2006/0114190 A1
(43) Pub. Date: Jun. 1, 2006

(54) ACTIVE MATRIX ORGANIC ELECTRO-LUMINESCENCE DEVICE ARRAY

(76) Inventors: Chun-Hsiang Fang, Yilan County (TW); Shih-Chang Chang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,547

(22) Filed: Nov. 16, 2004

(51) Int. Cl. G09G 3/30

(52) U.S. Cl. 345/76

(57) ABSTRACT

An active matrix organic electro-luminescence device array comprising first sub-pixel regions and second sub-pixel regions defined by scan lines and data lines is provided. Each first sub-pixel region has a first light emitting device, a first control unit and a second control unit therein while each second sub-pixel region has a second light emitting device therein. The first control unit is electrically connected to the first light emitting device for driving the first light emitting device. The second control unit is electrically connected to the second light emitting device for driving the second light emitting device. The second light emitting device having poor light emitting efficiency per unit area is disposed in the second sub-pixel region for increasing its light emitting area so that the first and second light emitting devices may have uniform brightness when drive with the same driving current.

### BACKGROUND OF THE INVENTION

1. Field of the Invention

The present invention generally relates to an electro-luminescence device. More particularly, the present invention relates to an active matrix organic electro-luminescence device array.

2. Description of Related Art

With recent advancement in opto-electronic fabricating techniques and the maturity of semiconductor manufacturing processes, the development of flat panel display devices have proceeded quite rapidly. In particular, organic electro-luminescence displays have the advantages of wide view angle, low production cost, high response speed, low power consumption, wide operating temperature range, lightness and small volume occupancy. Accordingly, the organic electro-luminescent display has potential applications and can become the main trend for the next generation displays.

The organic electro-luminescence displays include active matrix and passive matrix electro-luminescence displays. Generally, the light efficiency and lifetime of the passive matrix electro-luminescence display is deteriorated upon the advancing of large-size and high-resolution display. Hence, high-level active matrix organic electro-luminescence displays have been developed currently.

Every light emitting device of the organic electro-luminescence display comprises two electrodes and one organic emitting material layer. However, each organic emitting material has different light emitting efficiency. For example, the blue-light emitting device has poor light emitting efficiency relative to the red-light light emitting device and the green-light emitting device. Conventionally, the light emitting device having poor light emitting efficiency (blue-light emitting device) is driven with higher current to improve the whole displaying uniformity. This method usually causes these light emitting devices consisted of different organic emitting materials to have different aging degrees so as to deteriorate displaying quality.

FIG. 1 is a top view showing a conventional active matrix organic electro-luminescence device array. As shown in FIG. 1, the active matrix organic electro-luminescence device array 110 on a substrate 100 comprises scan lines 102, data lines 104, light emitting devices 106 and control units 112. The scan lines 102 and the data lines 104 are arranged on the substrate 100 to define many sub-pixel regions 108 (FIG. 1 only shows 3 sub-pixel regions). Each sub-pixel region 108 has one light emitting device 106 and one control unit 112 therein. The control unit 112 is used for driving the light emitting device 106. The light emitting device 106 is consisted of two electrodes and one organic emitting material layer. In addition, each control unit 112 is electrically connected to one power line 114 for supplying current to the control unit 112 to drive the light emitting device 106.

As shown in FIG. 1, for a full-color display device, the light emitting devices 106 of the active matrix organic electro-luminescence device array 110 usually comprises red-light emitting devices 106r, green-light emitting devices 106g and blue-light emitting devices 106b. In order to improve light emitting uniformity, red-light emitting devices 106r and the green-light emitting devices 106g having better light emitting efficiency relative to the blue-light emitting devices 106b are reduced. However, this method may deteriorate the aperture ratio of a portion of sub-pixel regions so as to restrict the displaying resolution and brightness.

Another conventional active matrix organic electro-luminescence device array is provided to resolve the above problem. FIG. 2 is a top view showing another conventional active matrix organic electro-luminescence device array. As shown in FIG. 2, the difference between the active matrix organic electro-luminescence device array 210 and the active matrix organic electro-luminescence device array 110 of FIG. 1 is that the sub-pixel regions 208a, 208b, 208c having different areas are designed. The blue light emitting device 106b having poor light emitting efficiency per unit area is disposed in the sub-pixel region 208c which has larger area so as to increase its light emitting efficiency. By this method, the aperture ratios of the sub-pixel regions having better light emitting efficiency (such as the sub-pixel region 208a and the sub-pixel region 208b in FIG. 2) are not restricted.

However, if the red light emitting devices 106r, green light emitting devices 106g and blue light emitting devices 106b disposed in the sub-pixel regions having different areas and arranged as delta arrangement are fabricated with inkjet printing process to form the polymeric light emitting material layers, the inkjet printing process may be performed more difficultly.

### SUMMARY OF THE INVENTION

Accordingly, the present invention is directed to an active matrix organic electro-luminescence device array capable of improving displaying uniformity and having good resolution and brightness. In addition, the light emitting devices of the array have identical lifetime.

The present invention is directed to a an active matrix organic electro-luminescence device array on a substrate comprising a plurality of scan lines, a plurality of data lines, a plurality of first light emitting devices, a plurality of second light emitting device, a plurality of first control units and a plurality of second control units. The scan lines and the data lines are arranged on the substrate to define a plurality of first sub-pixel regions and a plurality of second sub-pixel regions. Each first sub-pixel region is adjacent to at least one of the second sub-pixel regions. The first light emitting device, the first control unit and the second control unit are disposed in the first sub-pixel region, and the first light emitting device is electrically connected to the first control unit. The second light emitting device is disposed in the second sub-pixel region, and the second light emitting device is electrically connected the second control unit.

According to an embodiment of the present invention, the active matrix organic electro-luminescence device array further comprises a plurality of common power lines disposed inside the first sub-pixel regions. In each first sub-pixel region, the first control unit and the second control unit are electrically connected to the common power line. According to another embodiment of the present invention, the active matrix organic electro-luminescence device array further comprises a plurality of first power lines and a plurality of second power lines disposed inside the first sub-pixel regions. In each first sub-pixel region, the first control unit is electrically connected to the first power line, and the second control unit is electrically connected to the second power line.

According to an embodiment of the present invention, the first light emitting device and the second light emitting device are respectively an organic light emitting diode (OLED) or a polymeric light emitting diode (PLED). The second light emitting device is a blue-light emitting device, for example. In an embodiment, the second light emitting device has an emitting area larger than that of the first light emitting device, for example.

According to an embodiment of the present invention, the scan lines and the data lines further define a plurality of third sub-pixel regions. Each third sub-pixel region is adjacent to at least one of the first sub-pixel region and the second sub-pixel region. In addition, the active matrix organic electro-luminescence device array further comprises a plurality of third light emitting devices and a plurality of third control units. Each third light emitting device and each third control unit are disposed in each third sub-pixel region. In each third sub-pixel region, the third control unit is electrically connected to the third light emitting device.

According to an embodiment of the present invention, the active matrix organic electro-luminescence device array further comprises a plurality of third power lines. Each third power line is disposed inside the third sub-pixel region. In each third sub-pixel region, the third control unit is electrically connected to the third power line.

According to an embodiment of the present invention, the third light emitting device is an OLED or a PLED, for example. In an embodiment, the second light emitting device has an emitting area larger than that of the third light emitting device.

According to an embodiment of the present invention, the first light emitting devices and the second light emitting devices and the third light emitting devices are arranged as mosaic arrangement, delta arrangement, stripe arrangement or four-pixel arrangement.

The light emitting device having poor emitting efficiency per unit area can be disposed in the second sub-pixel region and its emitting area is increased so that the brightness of the light emitting device in the second sub-pixel region is similar to other light emitting devices when driving by the same current. These light emitting devices of the active matrix electro-luminescence device array have identical lifetimes. In addition, if the present invention is applied to an organic electric-luminescence display device, the organic electric-luminescence display has good displaying quality.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view showing a conventional active matrix organic electro-luminescence device array.

FIG. 2 is a top view showing another conventional active matrix organic electro-luminescence device array.

FIG. 3 is a top view showing an active matrix organic electro-luminescence device array according to an embodiment of the invention.

FIG. 4˜FIG. 7 are top views showing an active matrix organic electro-luminescence device array according to other embodiments of the invention.

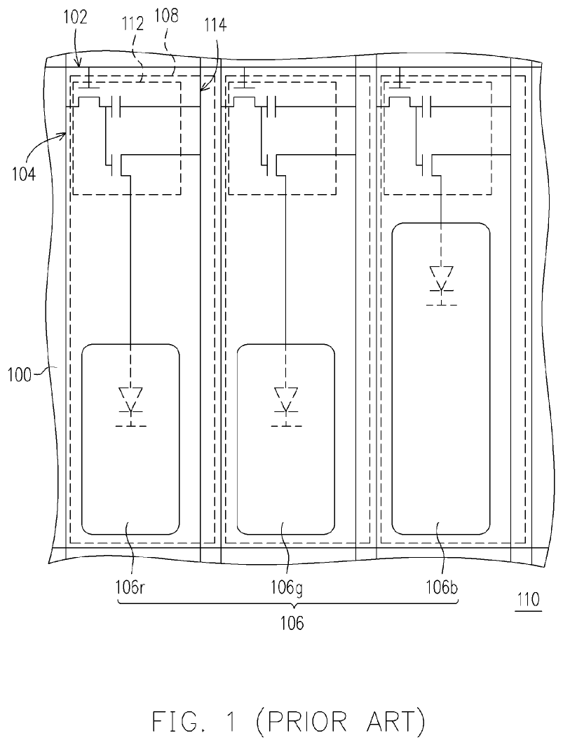

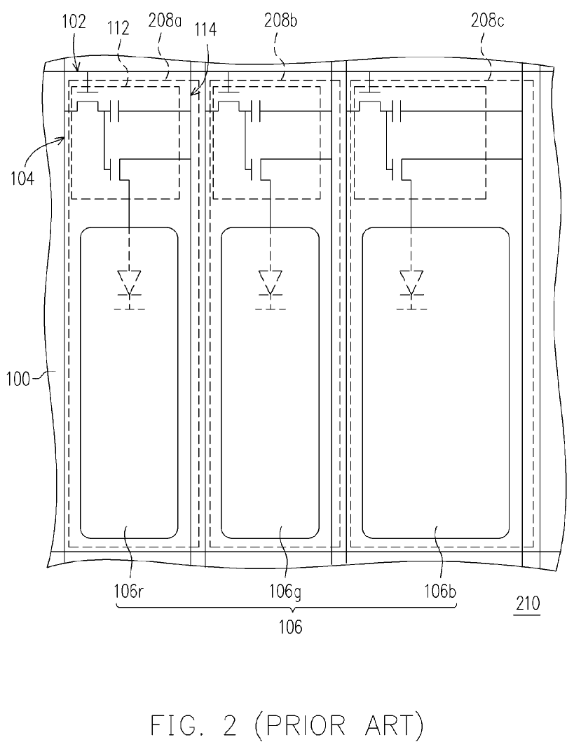

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the present invention, the light emitting device having poor light emitting efficiency is disposed in a sub-pixel region while its control unit is disposed in the adjacent sub-pixel region so as to increase the aperture ratio of the sub-pixel region in which the emitting device is disposed. Several embodiments are described as following but not for limiting the present invention. It will be apparent to those skilled in the art that various modifications and variations can be made to the structure of the present invention without departing from the scope or spirit of the invention.

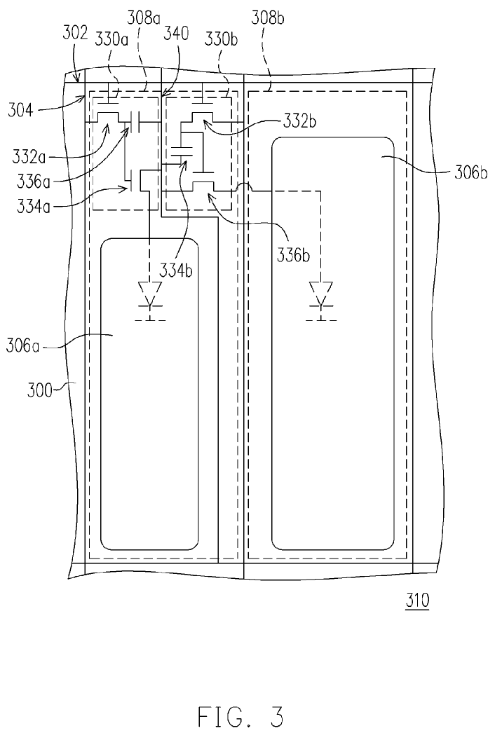

FIG. 3 is a top view showing a portion of an active matrix organic electro-luminescence device array according to an embodiment of the invention. As shown in FIG. 3, the active matrix organic electro-luminescence device array 310 is disposed on a substrate 300. The active matrix organic electro-luminescence device array 310 comprises a plurality of scan lines 302, a plurality of data lines 304, a plurality of first light emitting devices 306a, a plurality of second light emitting devices 306b, a plurality of first control units 330a and a plurality of second control units 330b. The scans lines 302 and the data lines 304 are arranged on the substrate 300 to define a plurality of first sub-pixel regions 308a and a plurality of second sub-pixel regions 308b. Preferably, the area of the first sub-pixel region 308a and that of the second sub-pixel region 308b are substantially identical. Each first sub-pixel region 308a is adjacent to at least one of the second sub-pixel regions 308b. FIG. 3 only shows one first sub-pixel region 308a and one second sub-pixel region for illustration.

As shown in FIG. 3, the second light emitting device 306b is disposed in the second sub-pixel region 308b. In particular, the first light emitting device 306a, the first control unit 330a and the second control unit 330b are all disposed in the first sub-pixel region 308a. The first control unit 330a is electrically connected to the first light emitting device 306a for driving the first light emitting device 306a while the second control unit 330b is electrically connected to the second light emitting device 306b for driving the second light emitting device 306b. The first control unit 330a and the second control unit 330b are electrically connected one of the scan lines 302 and one of the data lines 304 correspondingly.

In an embodiment, the first control unit 330a is consisted of two thin film transistors 332a, 334a and one capacitor 336a, wherein the thin film transistor 332a is a switching thin film transistor (TFT) for controlling signals input or not, and the thin film transistor 334a is a driving thin film transistor (TFT) for receiving signals from the thin film transistor 332a and drives the first light emitting device 306a. Similarly, the second control unit 330b is consisted of two thin film transistors 332b, 334b and one capacitor 336b, wherein the thin film transistor 332b is a switching thin film transistor for controlling signals input or not, and the thin film transistor 334b is a driving thin film transistor for receiving signals form the thin film transistor 332b and drives the second light emitting device 306b.

The first light emitting device 306a and the second light emitting device 306b are organic light emitting diodes (OLED) or polymeric light emitting diodes (PLED), for example. The first light emitting device 306a and the second light emitting device 306b are current-driving devices so that a plurality of power lines for supplying driving currents to the first/second light emitting device 306a, 306b are included in the active matrix organic electro-luminescence device array 310. The detail description is as following.

As shown in FIG. 3, in an embodiment, the active matrix organic electro-luminescence device array 310 further comprises a plurality of common power lines 340. Each common power line 340 is disposed inside each of the first sub-pixel region 308a, and the common power line 340 is electrically connected to the first control unit 330a and the second control unit 330b. The first control unit 330a is further described as following while the second control unit 330b is similar to the first control unit 330a and thus is omitted.

The gate of the switching TFT 332a of the first control unit 330a is electrically connected to the scan line 302, and the source and the drain are electrically connected to the data line 304 and the capacitor 336a respectively. In addition, the gate of the driving TFT 334a of the first control unit 330a is electrically connected to the drain of the switching TFT 332a. The drain and the source of the driving TFT 334a are respectively electrically connected to the first light emitting device 306a and the common power line 340. The driving current from the power line 340 is input into the driving TFT 334a through the source and the drain of the driving TFT 334a, and then is input into the first light emitting device 306a from the drain of the driving TFT 334a so as to induce the first light emitting device 306a to emit light.

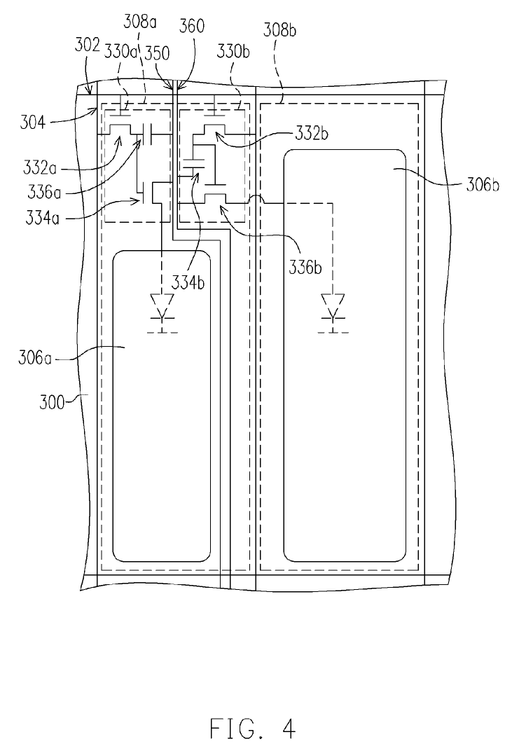

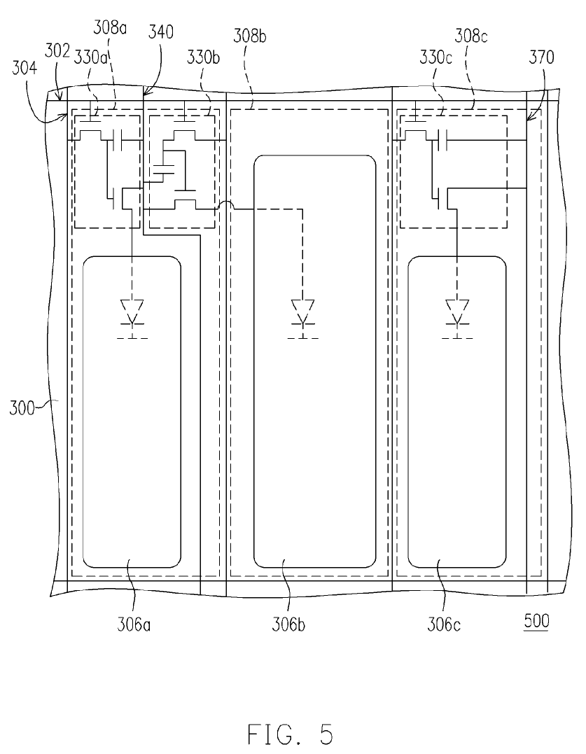

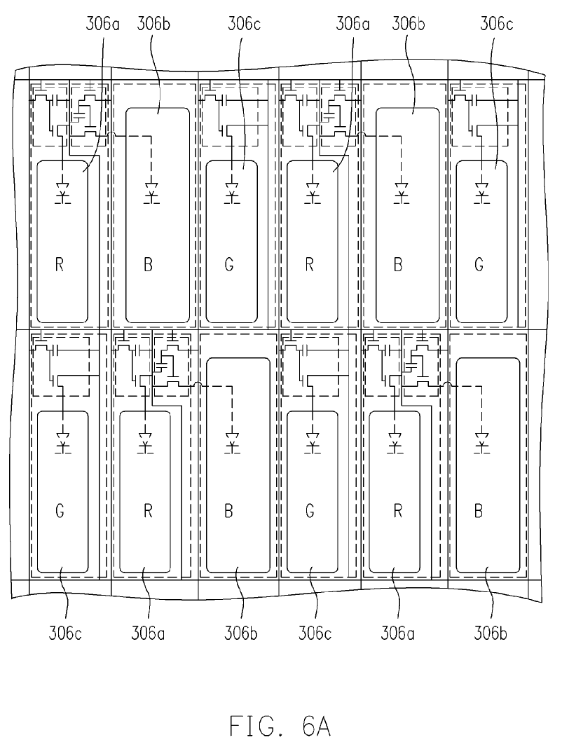

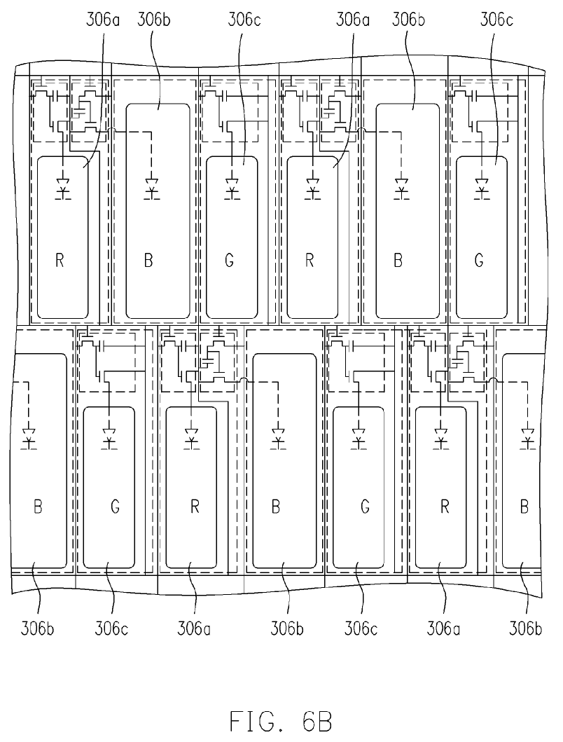

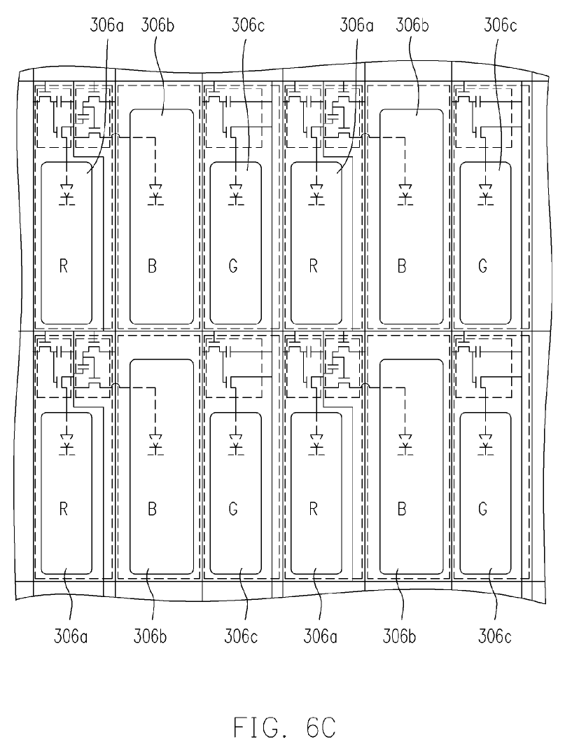

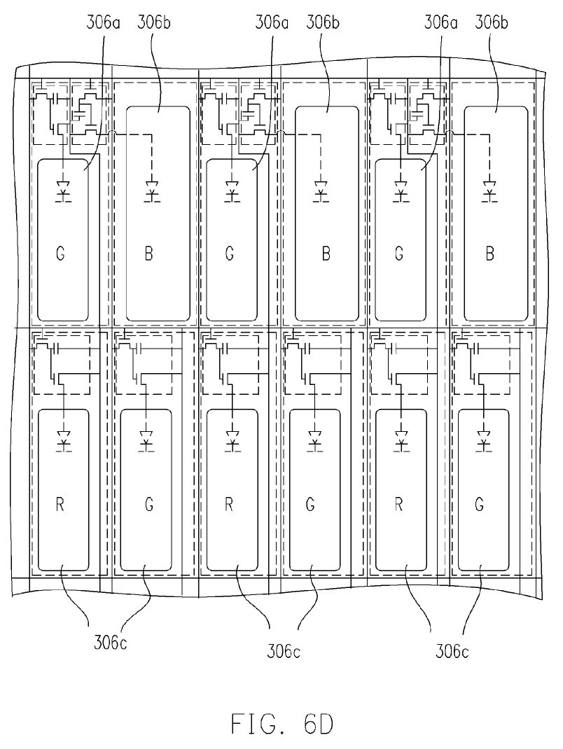

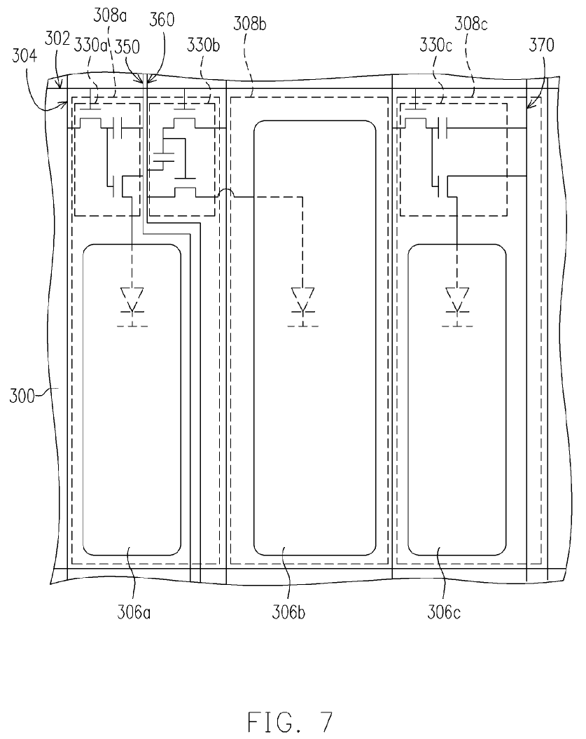

FIG. 4 is a top view showing a portion of an active matrix organic electro-luminescence device array according to another embodiment of the invention. As shown in FIG. 4, a first power line 350 and a second power line 360 are disposed inside the first sub-pixel region 308a, wherein the first power line 350 is electrically connected to the first control unit 330a while the second power line 360 is electrically connected to the second control unit 330b. In the present invention, the first control unit 330a and the second control unit 330b can be connected to one common power line or two respective power lines.

As shown in FIG. 3 and FIG. 4, each second sub-pixel regions 308b only has one second light emitting device 306b therein so that the emitting area of the second light emitting device 306b may be designed larger than that of the first light emitting device 306a. In an embodiment, the ratio of the emitting area of the second light emitting device 306b to the total area of the second sub-pixel 308b is about 80%, for example. The second light emitting device 306b may be a light emitting device having lower emitting efficiency per unit area. When the first light emitting device 306a and the second light emitting device 308b are driven with the same current, the active matrix electro-luminescence device array 310 has good brightness uniformity because the second light emitting device 306a has a larger emitting area.

Also, the emitting efficiency per unit area of the second light emitting device 306b may be not lower than that of the first light emitting device 306a. The above mentioned is an embodiment of the present invention. The present invention may also be applied to some devices having special requirements such as some particular light emitting device having higher brightness than other light emitting devices is needed.

For a full-color display device, one pixel region is usually composed of three sub-pixel regions, wherein red, green and blue-light emitting devices are respectively disposed in these three sub-pixel regions. The present invention can also be applied to a full color display device and is described as following.

FIG. 5 is a top view showing a portion of an active matrix organic electro-luminescence device array according to another embodiment of the invention. It is noted that the active matrix organic electro-luminescence device array of FIG. 5 is similar to the array of FIG. 3. The difference between them is described as following, and the same numbers in FIG. 5 refer to the same elements and are omitted.

As shown in FIG. 5, in the active matrix organic electro-luminescence device array 500, scan lines 302 and the data lines 304 are arranged on the substrate 300 to define a plurality of first sub-pixel regions 308a, a plurality of second sub-pixel regions 308b and a plurality of third sub-pixel regions 308c. FIG. 5 only shows one of the first sub-pixel regions 308a, one of the second sub-pixel regions 308b and one of the third sub-pixel regions 308c. Preferably, the areas of the first sub-pixel region 308a, the second sub-pixel region 308b and the third sub-pixel region 308c are substantially identical. The third sub-pixel region 308c is adjacent to least one of the first sub-pixel region 308a and the second sub-pixel region 308b.

As shown in FIG. 5, comparing with the active matrix organic electro-luminescence device array 300 of FIG. 3, the active matrix organic electro-luminescence device array 500 further comprises a plurality of third light emitting device 306c and a plurality of third control unit 330c. The third light emitting device 306c is an OLED or a PLED, for example. In particular, the first light emitting device 306a and the third light emitting device 306c are respectively a red-light emitting device or a green-light emitting device while the second light emitting device 306b is a blue-light emitting device. In an embodiment, the first light emitting device 306a, the second light emitting device 306b and the third light emitting device 306c are arranged as, for example, mosaic arrangement (as shown in FIG. 6A), delta arrangement (as shown in FIG. 6B), stripe arrangement (as shown in FIG. 6C) or four-pixel arrangement (as shown in FIG. 6D). In FIG. 6D, the first light emitting device 306a is a green-light emitting device G, and the second light emitting device 306b is a blue-light emitting device B. A portion of the third light emitting devices 306c disposed in the third sub-pixel regions 308c are red-light emitting devices R, for example, and another portion of the third light emitting devices 306c are green-light emitting devices G, for example. The arrangement of the first light emitting device 306a, the second light emitting device 306b and the third light emitting device 306c is not limited herein.

As shown in FIG. 5, the third light emitting device 306c and the third control unit 330c are disposed in the third sub-pixel region 308c. The third control unit 330c is electrically connected to the third light emitting device 306c for driving the third light emitting device 306c. In an embodiment, the third control unit 330c is consisted of two thin film transistors and one capacitor, and the third control unit 330c is driven by one of the scan lines 302 and one of the data lines 304 correspondingly.

Similarly, a third power line 370 is further disposed in the third sub-pixel region 308c and is electrically connected to the third control unit 330c to supply current for the third light emitting device 306c. In addition, the first control unit 330a and the second control unit 330b may be electrically connected to the common power line 240 (as shown in FIG. 5) or respectively electrically connected to the first power line 350 and the second power line 360 (as shown in FIG. 7).

It should be noted that since the common power line 340 has to be load higher current, the common power line 340 preferably has lower resistance to avoid burn-open. For example, if the same material is used for the power lines, the cross-sectional area of the common power line 340 is preferably larger than that of the third power line 370 or larger than that of the first power line 350 or the second power line 360 (as shown in FIG. 6). Also, a material having lower resistivity may be used to form the common power line 340.

For the foregoing, the present invention has advantages as following:
1. The second control unit for driving the second light emitting device is disposed in the first sub-pixel region so that the second sub-pixel region has sufficient area. In other words, the ratio of the emitting area of the second light emitting device to the area of the second sub-pixel region may increase to 80% so as to improve the aperture ratio of the second sub-pixel region. In the present invention, the emitting area of the second light emitting device is increased while that of other light emitting device is not decreased. Comparing with the conventional device, the active matrix electro-luminescence device array of the present invention has better resolution and brightness.
2. The light emitting device having poor emitting efficiency per unit area can be disposed in the second sub-pixel region and its emitting area is increased so that the brightness of the light emitting device in the second sub-pixel region is similar to other light emitting devices when driving by the same current. These light emitting devices of the active matrix electro-luminescence device array have identical lifetimes. In addition, if the present invention is applied to an organic electric-luminescence display device, the organic electric-luminescence display has good displaying quality.
3. The sub-pixel regions of the active matrix electro-luminescence device array have identical areas while the emitting area of the light emitting device having poor emitting efficiency is increased. Therefore, even if the inkjet printing process is utilized to form the light emitting device arranged as delta arrangement, the fabricating process is not complex because these sub-pixel regions have identical areas.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active matrix organic electro-luminescence device array, comprising:
a plurality of scan lines, arranged over a substrate;
a plurality of data lines, arranged over the substrate, wherein the data lines and the scan lines define a plurality of first sub-pixel regions and a plurality of second sub-pixel regions, and each first sub-pixel region is adjacent to at least one of the second sub-pixel regions;
a plurality of first light emitting devices, each first light emitting device is disposed in each first sub-pixel region;
a plurality of second light emitting devices, each second light emitting device is disposed in each second sub-pixel region;
a plurality of first control units, each first control unit is disposed in each first sub-pixel region and is driven by one of the scan lines and one of the data lines correspondingly, wherein the first control unit is electrically connected to the first light emitting device in the first sub-pixel region; and
a plurality of second control units, each second control unit is disposed in each first sub-pixel region and is driven by one of the scan lines and one of the data lines correspondingly, wherein the second control unit is electrically connected to the second light emitting device in the second sub-pixel region.

2. The active matrix organic electro-luminescence device array according to claim 1, further comprising a plurality of common power lines, each common power line is disposed inside each first sub-pixel region, wherein the common power line is electrically connected to the first control unit and the second control unit in the first sub-pixel region.

3. The active matrix organic electro-luminescence device array according to claim 1, further comprising a plurality of first power lines and a plurality of second power lines, each first power line and each second power line are both disposed inside each first sub-pixel region, wherein the first power line is electrically connected to the first control unit while the second power line is electrically connected to the second control unit.

4. The active matrix organic electro-luminescence device array according to claim 1, wherein the first light emitting devices and the second light emitting devices are organic light emitting diodes (OLED) or polymeric light emitting diodes (PLED).

5. The active matrix organic electro-luminescence device array according to claim 1, wherein the areas of the first sub-pixel region and the second sub-pixel region are substantially identical.

6. The active matrix organic electro-luminescence device array according to claim 1, wherein the second light emitting device has an emitting area larger than that of the first light emitting device.

7. The active matrix organic electro-luminescence device array according to claim 1, wherein the data lines and the scan lines further define a plurality of third sub-pixel regions, and each third sub-pixel region is adjacent to at least one of the first sub-pixel region and the second sub-pixel region, and the active matrix organic electro-luminescence device further comprises:
a plurality of third light emitting device, each third light emitting device is disposed in each third sub-pixel region; and
a plurality of third control units, each third control unit is disposed in each third sub-pixel region and is driven by one of the scan lines and one of the data lines correspondingly, wherein the third control unit is electrically connected to the third light emitting device.

8. The active matrix organic electro-luminescence device array according to claim 7, further comprising a plurality of third power lines, each third power line is disposed inside each third sub-pixel region, wherein the third power line is electrically connected to the third control unit in the third sub-pixel region.

9. The active matrix organic electro-luminescence device array according to claim 7, wherein the third light emitting device is an organic light emitting diode (OLED) or a polymeric light emitting diode (PLED).

10. The active matrix organic electro-luminescence device array according to claim 7, wherein the third light emitting device is a red-light emitting device or a green-light emitting device.

11. The active matrix organic electro-luminescence device array according to claim 7, wherein the second light emitting device is a blue-light emitting device.

12. The active matrix organic electro-luminescence device array according to claim 7, wherein the first light emitting device is a red-light emitting device or a green-light emitting device.

13. The active matrix organic electro-luminescence device array according to claim 7, wherein the areas of the first sub-pixel region, the second sub-pixel region and the third sub-pixel region are substantially identical.

14. The active matrix organic electro-luminescence device array according to claim 7, wherein the second light emitting device has an emitting area larger than that of the third light emitting device.

15. The active matrix organic electro-luminescence device array according to claim 7, wherein the first light emitting devices, the second light emitting devices and the third light emitting devices are arranged as mosaic arrangement, delta arrangement, stripe arrangement or four-pixel arrangement.
